(19) United States
(12) Patent Application Publication
(10) Pub. No.: US 2024/0304727 A1
(43) Pub. Date: Sep. 12, 2024

(54) DISPLAY APPARATUS AND FABRICATION METHOD THEREOF

(71) Applicant: Samsung Display Co., Ltd., Yongin-si (KR)

(72) Inventors: Eunhyun Kim, Yongin-si (KR); Jongbeom Ko, Yongin-si (KR); Yeonhong Kim, Yongin-si (KR); Yeonkeon Moon, Yongin-si (KR); Sunhee Lee, Yongin-si (KR); Junghoon Lee, Yongin-si (KR)

(21) Appl. No.: 18/525,551

(22) Filed: Nov. 30, 2023

(30) Foreign Application Priority Data
Mar. 10, 2023 (KR) 10-2023-0031877

(51) Int. Cl. H01L 29/786; H01L 29/423; H01L 29/66; H10K 59/12; H10K 59/121

(52) U.S. Cl. CPC H01L 29/7869; H01L 29/42384; H01L 29/66742; H10K 59/1201; H10K 59/1213

(57) ABSTRACT

A method of fabricating a display apparatus includes providing a substrate having a first thin film transistor region and a second thin film transistor region; forming a first oxide semiconductor layer on the substrate; forming a first gate insulating layer covering the first oxide semiconductor layer; forming a second oxide semiconductor layer on the substrate; forming a second gate insulating layer on the substrate; forming a first gate electrode in the first thin film transistor region and forming a second gate electrode in the second thin film transistor region, over the second gate insulating layer; and forming a first gate electrode stack and a second gate electrode stack by etching the first gate insulating layer and etching the second gate insulating layer by using the first gate electrode and the second gate electrode as etching masks.

### CROSS-REFERENCE TO RELATED APPLICATION

This application claims priority to and benefit of Korean Patent Application No. 10-2023-0031877, filed on Mar. 10, 2023, in the Korean Intellectual Property Office, the disclosure of which is incorporated by reference herein in its entirety.

### BACKGROUND

### 1. Field

Aspects of embodiments of the present disclosure relate to a thin film transistor (TFT) substrate and a display apparatus including the same.

### 2. Description of Related Art

Display apparatuses are apparatuses that visually display data. A display apparatus may be used as a display for small-sized products such as mobile phones or for large-sized products such as televisions.

A display apparatus includes a plurality of pixels that, upon receiving electrical signals, emit light to display an image to the outside. Each pixel includes a light-emitting device, and an organic light-emitting display apparatus includes an organic light-emitting diode (OLED) as a light-emitting device. In general, an organic light-emitting display apparatus includes a thin film transistor and an organic light-emitting diode disposed on a substrate and operates by self-emission of light of the light-emitting diodes.

Recently, as the use of display apparatuses has diversified, various attempts have been made to improve the quality of display apparatuses.

The above information disclosed in this Background section is only for enhancement of understanding of the background of the invention and therefore it may contain information that does not form the prior art.

### SUMMARY

Aspects of some embodiments of the present disclosure are directed to a display apparatus including heterogenous thin film transistors in which characteristics of the thin film transistors may be obtained and a fabrication method thereof.

Additional aspects will be set forth in part in the description which follows and, in part, will be apparent from the description, or may be learned by practice of the presented embodiments of the disclosure.

According to some embodiments of the present disclosure, there is provided a method of fabricating a display apparatus, the method including: providing a substrate having a first thin film transistor region and a second thin film transistor region; forming a first oxide semiconductor layer on the substrate in the first thin film transistor region; forming a first gate insulating layer covering the first oxide semiconductor layer in the first thin film transistor region; forming a second oxide semiconductor layer on the substrate in the second thin film transistor region; forming a second gate insulating layer on the substrate on which the first gate insulating layer and the second oxide semiconductor layer are formed; forming a first gate electrode in the first thin film transistor region and forming a second gate electrode in the second thin film transistor region, over the second gate insulating layer; and forming a first gate electrode stack and a second gate electrode stack by etching the first gate insulating layer, which is under the first gate electrode, and etching the second gate insulating layer, which is under the first and second gate electrodes, by using the first gate electrode and the second gate electrode as etching masks.

In some embodiments, the forming of the first gate insulating layer includes: forming an insulating layer for the first gate insulating layer on the substrate; and removing a portion of the insulating layer from the second thin film transistor region.

In some embodiments, the method further includes: forming an interlayer insulating layer on the substrate; forming, on the interlayer insulating layer, a first source electrode and a first drain electrode to be in contact with the first oxide semiconductor layer, and a second source electrode and a second drain electrode to be in contact with the second oxide semiconductor layer; forming a planarization layer on the interlayer insulating layer, the first source electrode, the first drain electrode, the second source electrode, and the second drain electrode; and forming an organic light-emitting device that is connected to the first source electrode or the first drain electrode on the planarization layer.

In some embodiments, a thickness of each of the first gate insulating layer and the second gate insulating layer is from about 600 Å to about 2000 Å.

In some embodiments, each of the first gate insulating layer and the second gate insulating layer includes at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂).

In some embodiments, the first gate insulating layer and the second gate insulating layer are formed of a same material.

In some embodiments, the first gate insulating layer and the second gate insulating layer are formed of different materials from each other.

In some embodiments, a concentration of hydrogen in the first gate insulating layer is higher than a concentration of hydrogen in the second gate insulating layer.

In some embodiments, the second oxide semiconductor layer has a higher electron mobility than that of the first oxide semiconductor layer.

In some embodiments, the first oxide semiconductor layer has an electron mobility of about 1 to about 20 cm²/V·s, and the second oxide semiconductor layer has an electron mobility of about 30 to about 80 cm²/V·s.

In some embodiments, each of the first oxide semiconductor layer and the second oxide semiconductor layer includes an indium-gallium-zinc oxide (InGaZnO), a hafnium-indium-zinc oxide (HfInZnO), an indium-tin-zinc oxide (InSnZnO), an aluminum-indium-tin oxide (AlInZnO), a gallium-tin-zinc oxide (GaSnZnO), a gallium-aluminum-zinc oxide (GaAlZnO), an aluminum-tin-zinc oxide (AlSnZnO), an indium-zinc oxide (InZnO), an indium-gallium oxide (InGaO), a zinc-tin oxide (ZnSnO), an aluminum-tin oxide (AlZnO), or any combination thereof.

In some embodiments, the first oxide semiconductor layer includes InGaZnO, HfInZnO, AlInZnO, InZnO, InGaO, AlZnO, or any combination thereof, and the second oxide semiconductor layer includes InSnZnO, InSnGaZnO, GaSnZnO, ZnSnO, or any combination thereof.

In some embodiments, the substrate further includes: a first bottom metal layer in the first thin film transistor region; a second bottom metal layer in the second thin film transistor region; and a buffer layer on the first bottom metal layer and the second bottom metal layer, wherein the first gate electrode and the first bottom metal layer face each other, and the second gate electrode and the second bottom metal layer face each other.

According to some embodiments of the present disclosure, there is provided a display apparatus including: an organic light-emitting device; a first thin film transistor connected to the organic light-emitting device; and a second thin film transistor on a same plane as that of the first thin film transistor, wherein the first thin film transistor includes: a first oxide semiconductor layer; a first gate electrode stack including a first gate insulating layer on the first oxide semiconductor layer, a second gate insulating layer on the first gate insulating layer, and a first gate electrode on the second gate insulating layer; and a first source electrode and a first drain electrode, both contacting the first oxide semiconductor layer, wherein the second thin film transistor includes: a second oxide semiconductor layer; a second gate electrode stack including a second gate insulating layer on the second oxide semiconductor layer, and a second gate electrode on the second gate insulating layer; and a second source electrode and a second drain electrode, both contacting the second oxide semiconductor layer, wherein an electron mobility of the second oxide semiconductor layer is higher than that of the first oxide semiconductor layer.

In some embodiments, each of the first gate electrode and the second gate electrode includes one of aluminum (Al), titanium (Ti), tungsten (W), copper (Cu), molybdenum (Mo), platinum (Pt), palladium (Pd), ruthenium (Ru), silver (Ag), magnesium (Mg), gold (Au), nickel (Ni), neodymium (Nd), iridium (Ir), and chromium (Cr), or an alloy, nitride, or conductive oxide thereof.

In some embodiments, the first thin film transistor is a driving thin film transistor connected to the organic light-emitting device, and the second thin film transistor is a switching thin film transistor connected to the driving thin film transistor.

In some embodiments, each of the first oxide semiconductor layer and the second oxide semiconductor layer includes an indium-gallium-zinc oxide (InGaZnO), a hafnium-indium-zinc oxide (HfInZnO), an indium-tin-zinc oxide (InSnZnO), an aluminum-indium-tin oxide (AlInZnO), a gallium-tin-zinc oxide (GaSnZnO), a gallium-aluminum-zinc oxide (GaAlZnO), an aluminum-tin-zinc oxide (AlSnZnO), an indium-zinc oxide (InZnO), an indium-gallium oxide (InGaO), a zinc-tin oxide (ZnSnO), an aluminum-tin oxide (AlZnO), or any combination thereof.

In some embodiments, a total thickness of the first gate insulating layer and the second gate insulating layer, between the first oxide semiconductor layer and the first gate electrode, is greater than a thickness of the second gate insulating layer between the second oxide semiconductor layer and the second gate electrode.

In some embodiments, the display apparatus further includes: a first bottom metal layer under the first oxide semiconductor layer and overlapping the first gate electrode stack; a second bottom metal layer under the second oxide semiconductor layer and overlapping the second gate electrode stack; and a buffer layer between the first gate electrode stack and the first bottom metal layer and between the second gate electrode stack and the second bottom metal layer.

In some embodiments, the display apparatus includes a flat panel display, a curved display, a computer monitor, a medical monitor, a television, a billboard, a light for indoor or outdoor lighting and/or signal lighting, a head-up display, a fully or partially transparent display, a flexible display, a rollable display, a foldable display, a stretchable display, a laser printer, a phone, a mobile phone, a tablet, a phablet, a personal digital assistant (PDA), a wearable device, a laptop computer, a digital camera, a camcorder, a viewfinder, a microdisplay, a 3D display, a virtual reality or augmented reality display, a vehicle, a video wall including multiple displays tiled together, a theater or stadium screen, a phototherapy device, or a signage.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display apparatus according to some embodiments of the present disclosure.

FIG. 2 is an equivalent circuit diagram of a pixel of a display apparatus according to some embodiments of the present disclosure.

FIG. 3 is a schematic cross-sectional view of a display apparatus according to some embodiments of the present disclosure.

FIGS. 4 to 11 are cross-sectional views sequentially illustrating a method of fabricating the display apparatus of FIG. 3, according to some embodiments of the present disclosure.

FIG. 12 is a graph illustrating gate-source voltages V_{GS} with respect to drain-source currents I_{DS} of one of 15 thin film transistors prepared in Experimental Example 1.

FIG. 13 is a graph of gate-source voltages V_{GS} with respect to drain-source currents I_{DS} of one of 15 thin film transistors prepared in Comparative Example 1.

### DETAILED DESCRIPTION

Reference will now be made in detail to embodiments of the present disclosure, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As the disclosure below allows for various suitable changes and numerous embodiments, particular embodiments will be illustrated in the drawings and described in detail in the written description. Effects and features of the disclosure and a method of achieving the effects and features will be apparent by referring to embodiments described below in connection with the accompanying drawings. However, the disclosure is not restricted by these embodiments and can be implemented in many different suitable forms.

Hereinafter, embodiments will be described in detail with reference to the accompanying drawings. In the drawings, like reference numerals denote like elements or components having substantially same functions, and duplicate descriptions will be omitted.

An expression used in the singular encompasses the expression of the plural unless it has a clearly different meaning in the context.

Also, sizes of elements in the drawings may be exaggerated or reduced for convenience of explanation. For example, since sizes and thicknesses of components in the drawings are arbitrarily illustrated for convenience of explanation, the following embodiments are not limited thereto.

A display apparatus, as an apparatus visually displaying images, may be an organic light-emitting display apparatus, an inorganic light-emitting display apparatus, a quantum dot light-emitting display apparatus, a field emission display apparatus, a surface-conduction electron-emitter display apparatus, a plasma display apparatus, or the like.

### Display Apparatus

Hereinafter, an organic light-emitting display apparatus is described as an example of a display apparatus according to some embodiments of the present disclosure, but the display apparatus of the disclosure is not limited thereto, and various other suitable types of display apparatuses may be used.

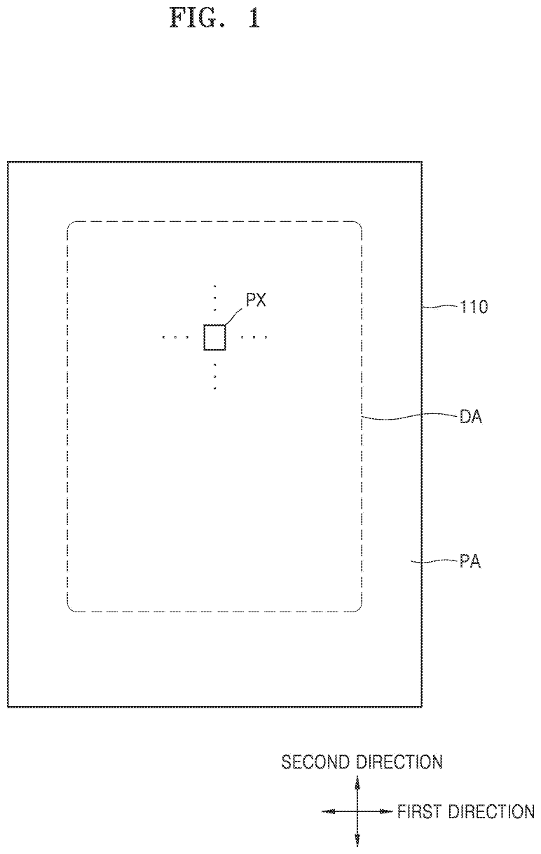

FIG. 1 is a plan view schematically illustrating a display apparatus according to some embodiments of the present disclosure.

Referring to FIG. 1, a display apparatus 1 includes a display area DA including a pixel PX to implement an image and a peripheral area PA in which an image is not implemented (e.g., in which an image cannot be displayed).

The display apparatus 1 may provide an image to the outside using light emitted from the pixels PX located in the display area DA. Each pixel PX includes a light-emitting device and may further include a device such as a thin film transistor (TFT) and a capacitor.

The peripheral area PA includes components configured to provide electrical signals to the pixels PX of the display area DA such as a scan driver and a data driver and power lines configured to provide power through, for example, a driving voltage and a common voltage.

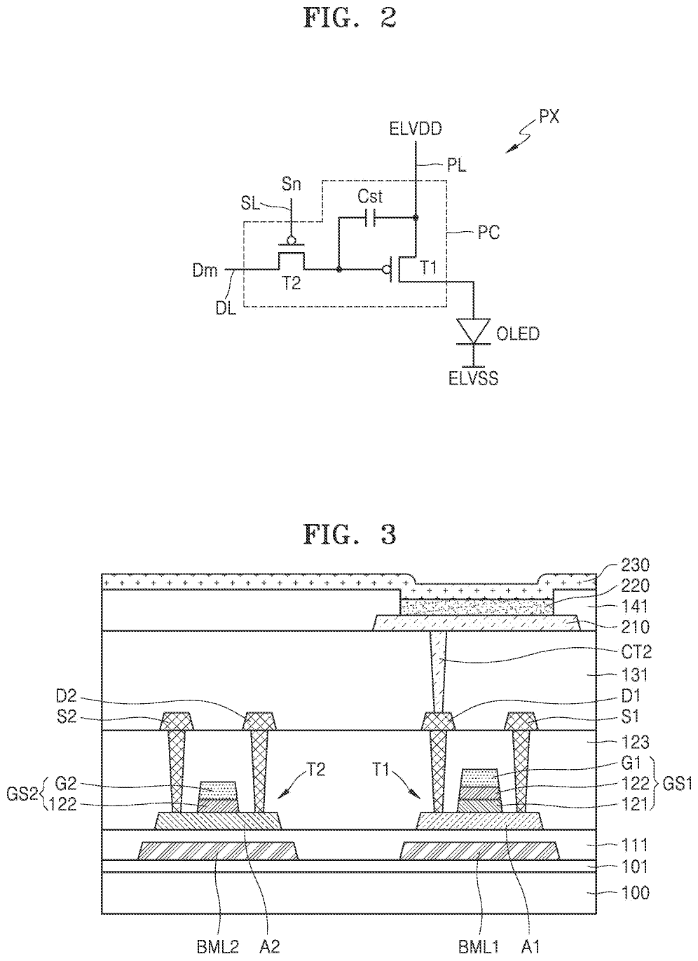

FIG. 2 is an equivalent circuit diagram of a pixel of a display apparatus according to some embodiments of the present disclosure.

Referring to FIG. 2, each pixel PX includes a pixel circuit connected to a driving voltage line PL, a scan line SL, a data line DL, and an organic light-emitting diode OLED connected to the pixel circuit PC.

The pixel circuit PC includes a driving thin film transistor T1, a switching thin film transistor T2, and a storage capacitor Cst. The switching thin film transistor T2 is connected to the scan line SL and the data line DL and transmit a data signal Dm input through the data line DL to the driving thin film transistor T1 in accordance with a scan signal Sn input through the scan line SL.

The storage capacitor Cst is connected to the switching thin film transistor T2 and the driving voltage line PL and stores a voltage received from the switching thin film transistor T2 and a driving voltage supplied to the driving voltage line PL, i.e., a voltage corresponding to a difference between the first supply voltage (e.g., ELVDD) and the common voltage (e.g., ELVSS).

The driving thin film transistor T1 is connected to the driving voltage line PL and the storage capacitor Cst and may control a driving current flowing in the organic light-emitting diode OLED from the driving voltage line PL in response to a voltage stored in the storage capacitor storage capacitor Cst. The organic light-emitting diode OLED may emit light having a preset luminance by a driving current.

Although a pixel circuit PC including two thin film transistors and one storage capacitor is illustrated in FIG. 2, the disclosure is not limited thereto. According to some other embodiments, the pixel circuit PC includes seven thin film transistors and one storage capacitor. Further, the pixel circuit PC may also include two or more storage capacitors.

FIG. 3 is a schematic cross-sectional view of a display apparatus according to some embodiments of the present disclosure.

Referring to FIG. 3, a display apparatus according to some embodiments includes a pixel circuit PC located in a display area DA of a substrate 100 and an organic light-emitting diode OLED, as a display element, connected to the pixel circuit PC. The pixel circuit PC includes a driving thin film transistor T1 and a switching thin film transistor T2.

In some embodiments, the driving thin film transistor T1 includes a driving semiconductor layer A1 and the switching thin film transistor T2 includes a switching semiconductor layer A2.

In the display area DA of FIG. 3, among the elements of the pixel circuit PC of each pixel PX described above with reference to FIG. 2, the driving thin film transistor T1 and the switching thin film transistor T2 are illustrated. For descriptive convenience, a configuration shown in FIG. 3 is described sequentially in a stacking order (e.g., from a bottom layer to a top layer).

The substrate 100 may include a glass material, a metallic material, a polymer resin, and/or the like. The polymer resin may include, for example, polyethersulfone, polyacrylate, polyetherimide, polyethylene naphthalate, polyethylene terephthalate, polyphenylene sulfide, polyarylate, polyimide, polycarbonate, cellulose acetate propionate, and/or the like. The substrate 100 may have a single-layered or a multi-layered structure of the noted materials, and may further include an inorganic layer in the case of the multi-layered structure.

The driving thin film transistor T1 and the switching thin film transistor T2 may include a bottom metal layer BML (BML1 and BML2, respectively). A gate electrode of the driving thin film transistor T1 and the bottom metal layer BML1 may overlap each other with an insulating layer disposed therebetween, and the gate electrode of the switching thin film transistor T2 and the bottom metal layer BML2 may overlap each other with an insulating layer disposed therebetween. In some embodiments, the bottom metal layers BML1 and BML2 is electrically connected to electrodes of thin film transistors T1 and T2, for example, source electrodes S1 and S2 or drain electrodes D1 and D2, respectively.

In some embodiments, a back-biasing technique (or a sync technique) of moving threshold voltages of the thin film transistors T1 and T2 in a negative or positive direction by applying a back-biasing voltage to the bottom metal layers BML1 and BML2 of the thin film transistors T1 and T2 is used. For example, by applying a source-sync or gate-sync technique by connecting the bottom metal layers BML1 and BML2 with the source electrode or the gate electrode of the thin film transistors T1 and T2, the threshold voltages of the thin film transistors T1 and T2 may be moved in the negative or positive direction. In addition, in the case where the bottom metal layers BML1 and BML2 are disposed under the semiconductor layers A1 and A2 constituting channels of the thin film transistors T1 and T2, the bottom metal layers BML1 and BML2 may stabilize operating characteristics of the thin film transistors T1 and T2 while serving as patterns to block light incident on the semiconductor layers A1 and A2. However, functions and/or utilization methods of the bottom metal layers BML1 and BML2 are not limited thereto.

The bottom metal layers BML1 and BML2 may include a conductive material including, for example, molybdenum (Mo), aluminum (Al), copper (Cu), and titanium (Ti) and may be formed in a single layer or multilayers including the materials. The bottom metal layers BML1 and BML2 may have, for example, a Ti/Al/Ti-multi-layered structure.

The buffer layer 111 may be formed on the entire surface of the substrate 100 to cover the bottom metal layers BML1 and BML2. The buffer layer 111 may serve to prevent or substantially reduce (e.g., minimize) penetration of impurities from the substrate 100, or the like, into the semiconductor layers A1 and A2. The buffer layer 111 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and/or the like. In some embodiments, a lower buffer layer 101 is disposed between the substrate 100 and the bottom metal layers BML1 and BML2.

The driving semiconductor layer A1 of the driving thin film transistor T1 and the switching semiconductor layer A2 of the switching thin film transistor T2 may be disposed on the buffer layer 111.

The driving semiconductor layer A1 and the switching semiconductor layer A2 may include an oxide semiconductor material. For example, the oxide semiconductor material may include an oxide of at least one material selected from indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The oxide semiconductor material may include, for example, an indium-gallium-zinc oxide (InGaZnO), a hafnium-indium-zinc oxide (HfInZnO), an indium-tin-zinc oxide (InSnZnO), an aluminum-indium-tin oxide (AlInZnO), a gallium-tin-zinc oxide (GaSnZnO), a gallium-aluminum-zinc oxide (GaAlZnO), an aluminum-tin-zinc oxide (AlSnZnO), an indium-zinc oxide (InZnO), a zinc-tin oxide (ZnSnO), an aluminum-tin oxide (AlZnO), or any combination thereof.

In some embodiments, the switching semiconductor layer A2 is formed of a material having a higher electron mobility than that of the driving semiconductor layer A1. Because a high operating speed is important for the switching thin film transistor T2, the switching semiconductor layer A2 may be formed of a material having a high electron mobility. On the other hand, a precise control of current within a driving range rather than high electron mobility is important for the driving semiconductor layer A1. In some examples, the driving semiconductor layer A1 may have an electron mobility of about 1 cm²/V·s to about 20 cm²/V·s, and the switching semiconductor layer A2 may have an electron mobility of about 30 cm²/V·s to about 80 cm²/V·s.

In some embodiments, the driving semiconductor layer A1 includes at least one of InGaZnO, HfInZnO, AlInZnO, InZnO, InGaO, AlZnO, and the switching semiconductor layer A2 includes at least one of InSnZnO, InSnGaZnO, GaSnZnO, and ZnSnO.

The driving semiconductor layer A1 and the switching semiconductor layer A2 may include a channel region and a source region and a drain region located at both sides of the channel region.

A first gate insulating layer 121 and a second gate insulating layer 122 may be arranged to correspond to the channel region of the driving semiconductor layer A1, and the second gate insulating layer 122 may be arranged to correspond to the channel region of the switching semiconductor layer A1.

The gate insulating layers 121 and 122 may be formed of an inorganic insulating material. The gate insulating layers 121 and 122 may include, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂).

While switch speed is important for a switching thin film transistor, driving ability to precisely adjust a current supplied to the light-emitting device is important for the driving thin film transistor. Because a gate insulating layer may affect the speed or the driving ability of a transistor, characteristics required for both the driving thin film transistor and the switching thin film transistor may not be satisfied at the same time in the case of applying the same gate insulating layer to the switching thin film transistor and the driving thin film transistor.

In some embodiments, the gate insulating layer of the driving thin film transistor T1 includes a double layer of the first gate insulating layer 121 and the second gate insulating layer 122, and the gate insulating layer of the switching thin film transistor T2 includes a single layer of the second gate insulating layer 122. Because the first gate insulating layer 121 may be formed to have characteristics suitable for the driving thin film transistor, a freedom of the fabrication process may be increased. In addition, by omitting the first gate insulating layer 121 under the switching semiconductor layer A2 of the switching thin film transistor T2, characteristics of the switching thin film transistor T2 may be easily obtained. For example, by designing the first gate insulating layer 121 to have a higher oxygen or hydrogen concentration than that of the second gate insulating layer 122, driving characteristics of the driving thin film transistor may further be improved. In this case, because oxygen or hydrogen is not introduced into the switching semiconductor layer A2 from the first gate insulating layer 121, characteristics of the switching thin film transistor T2 may be improved.

In some examples, the first gate insulating layer 121 may have a thickness of, for example, 600 Å to 2000 Å or, for example, 600 Å to 1000 Å. The second gate insulating layer 122 may have a thickness of, for example, about 600 Å to about 2000 Å or, for example, about 1400 Å to about 2000 Å. As a hydrogen concentration of the first gate insulating layer 121 increases, reliability of the driving thin film transistor T1 may be obtained more easily.

Gate electrodes G1 and G2 are disposed on the gate insulating layers of the driving thin film transistor T1 and the switching thin film transistor T2. The gate electrodes G1 and G2 may be formed concurrently (e.g., simultaneously) with the gate insulating layers 121 and 122 by patterning. Accordingly, sides of the gate electrodes G1 and G2 may meet sides of the gate insulating layers 121 and 122. The gate electrodes G1 and G2 may include one of aluminum (Al), titanium (Ti), tungsten (W), copper (Cu), molybdenum (Mo), platinum (Pt), palladium (Pd), ruthenium (Ru), silver (Ag), magnesium (Mg), gold (Au), nickel (Ni), neodymium (Nd), iridium (Ir), or chromium (Cr), or an alloy, nitride, or conductive oxide thereof, and may be formed in a single-layered or multi-layered structure. The gate electrodes G1 and G2 may include, for example, Ti/Al, Ti/Mo, or Ti/Al/Ti, but are not limited thereto.

An interlayer insulating layer 123 may be provided to cover the gate electrodes G1 and G2. The interlayer insulating layer 123 may have a single layer or may have multi layers of an inorganic material or an organic material. In the case of including an inorganic material, the interlayer insulating layer 123 may include, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). In the case of including an organic material, the interlayer insulating layer 123 may include an insulating material such as an acrylic resin, an epoxy resin, a phenol resin, a polyamide resin, a polyimide resin, and/or the like.

On the interlayer insulating layer 123, a driving source electrode S1 and a driving drain electrode D1 of the driving thin film transistor T1, a switching source electrode S2 and a switching drain electrode D2 of the switching thin film transistor T2, a data line, a driving voltage line, and the like may be disposed.

The source electrodes S1 and S2, the drain electrodes D1 and D2, the data line DL, and the driving voltage line PL may include aluminum (Al), titanium (Ti), tungsten (W), copper (Cu), molybdenum (Mo), platinum (Pt), palladium (Pd), silver (Ag), magnesium (Mg), gold (Au), nickel (Ni), neodymium (Nd), iridium (Ir), chromium (Cr), and/or the like, and may be formed as a single-layer structure or a multilayer structure. The source electrodes S1 and S2 and the drain electrodes D1 and D2 may be connected to a source region or a drain region of the semiconductor layers A1 and A2 via contacts in the interlayer insulating layer 123. In addition, according to some embodiments, the source electrodes S1 and S2 or the drain electrodes D1 and D2 is connected to the bottom metal layers BML1 and BML2 via corresponding contacts.

A planarization layer 131 may be disposed on the source electrodes S1 and S2, the drain electrodes D1 and D2, a data line, and a driving voltage line, and an organic light-emitting diode OLED may be disposed on the planarization layer 131. The planarization layer 131 may be formed with an organic material as a single-layer or multilayer structure and may provide a planar top surface. The planarization layer 131 may be formed of an organic insulating material such as an acrylic resin, an epoxy resin, a phenol resin, a polyamide resin, a polyimide resin, and/or the like. In some embodiments, the source electrodes S1 and S2 and the drain electrodes D1 and D2 are covered with a protective layer. The protective layer may include an inorganic insulating layer of a single-layer structure or may include a multilayer structure of silicon nitride (SiNₓ) and silicon oxide (SiO₂). In some examples, the protective layer may be formed of an organic insulating layer.

In the display area DA of the substrate 100, the organic light-emitting diode OLED is positioned on the planarization layer 131. The organic light-emitting diode OLED includes a pixel electrode 210, an intermediate layer 220 including an organic emission layer, and an opposite electrode 230.

The pixel electrode 210 may be a transmissive electrode, a semi-transmissive electrode, or a reflective electrode. In some embodiments, the pixel electrode 210 includes a reflective layer formed of silver (Ag), magnesium (Mg), aluminum(Al), platinum (Pt), palladium (Pd), gold (Au), nickel (Ni), neodymium (Nd), iridium (Ir), chromium (Cr), or a compound thereof, and a transparent or semi-transparent electrode layer formed on the reflective layer. The transparent or semi-transparent electrode layer includes an indium-tin oxide (ITO), an indium-zinc oxide (IZO), a zinc oxide (ZnO), an indium oxide (In₂O₃), an indium-gallium oxide (IGO), an aluminum-zinc oxide (AZO), or any combination thereof. In some embodiments, the pixel electrode 210 includes ITO/Ag/ITO.

A pixel-defining layer 141 may be disposed on the planarization layer 131. The pixel-defining layer 141 may serve to define an emission region of a pixel by having an opening corresponding to each sub pixel in the display area DA, i.e., an opening configured to expose at least a central region of the pixel electrode 210. Also, the pixel-defining layer 141 may serve to prevent an arc (e.g., an electrical arc or discharge), or the like from occurring at edges of the pixel electrode 210 by increasing distances between edges of the pixel electrode 210 and edges of an opposite electrode 230 disposed above the pixel electrode 210. The pixel-defining layer 141 may be formed of an organic insulating material such as an acrylic resin, an epoxy resin, a phenol resin, a polyamide resin, and a polyimide resin.

The intermediate layer 220 of the organic light-emitting diode OLED may include an emission layer. The emission layer may include an organic material including a fluorescent or phosphorescent material emitting red, green, blue, or white light. The organic material may be a low-molecular compound or a polymer compound. In some examples, the emission layer may include an inorganic material such as quantum dots. In some examples, functional layers such as a hole transport layer (HTL), a hole injection layer (HIL), an electron transport layer (ETL), and an electron injection layer (EIL) may further be disposed on and under the emission layer. The intermediate layer 220 may be located to correspond to each of the plurality of pixel electrodes 210; however, embodiments of the present disclosure are not limited thereto. The intermediate layer 220 may include a common layer disposed over the pixel electrodes 210, and various other suitable modifications may be made.

The opposite electrode 230 may be a transmissive electrode or a reflective electrode. In some embodiments, the opposite electrode 230 is a transparent or a semi-transparent electrode formed of a metal thin film with a low work function including lithium (Li), calcium (Ca), lithium/calcium (LiF/Ca), lithium/aluminum (LiF/Al), aluminum (Al), silver (Ag), magnesium (Mg), or a compound thereof. In addition, a transparent conductive oxide (TCO) layer such as ITO, IZO, ZnO or In₂O₃ may further be disposed on the metal thin film. The opposite electrode 230 may be formed as a common layer with respect to the plurality of pixels.

The pixel electrode 210 may be connected to the driving drain electrode D1 of the driving thin film transistor T1 via a contact CT2 as illustrated herein or may be electrically connected to the driving drain electrode D1 via an intervening medium such as a connecting electrode.

### Fabrication Method

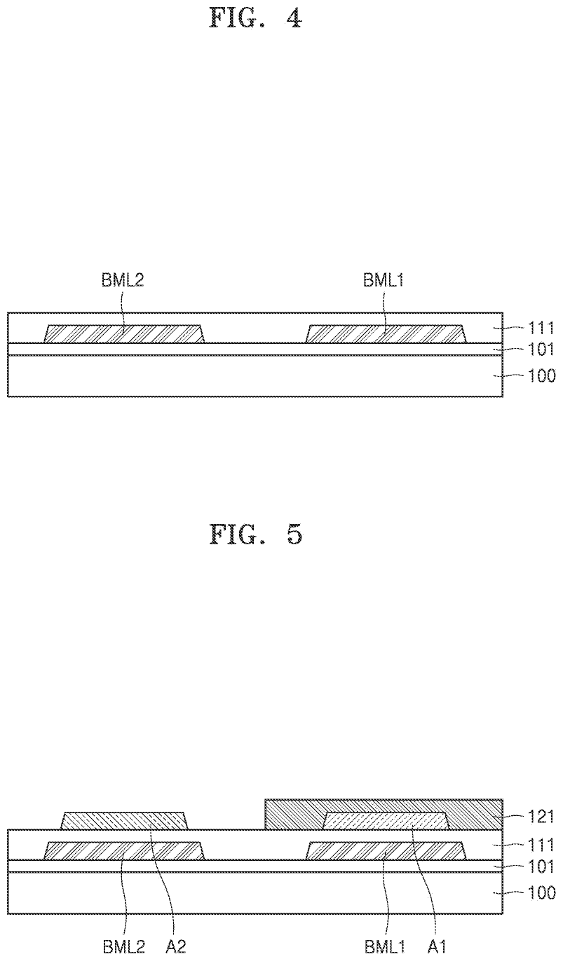

FIGS. 4 to 11 are cross-sectional views sequentially illustrating a method of fabricating a display apparatus of FIG. 3, according to some embodiments of the present disclosure. Layers (or patterns) formed during the fabrication method are identical to layers (or patterns) of the display apparatus illustrated in FIG. 3. Therefore, materials included in each of the layers (or patterns) and functions thereof are the same as those described above with reference to FIG. 3, and thus hereinafter, duplicate descriptions may not be repeated.

Referring to FIG. 4, the bottom metal layer BML1 is formed in a region of the substrate 100 where the driving thin film transistor T1 is to be formed, and the bottom metal layer BML2 is formed in a region where the switching thin film transistor T2 is to be formed. In this regard, a barrier layer 101 formed of an inorganic material may be formed between the substrate 100 and the bottom metal layers BML1 and BML2. The bottom metal layers BML1 and BML2 may be formed of a conductive material including molybdenum (Mo), aluminum (Al), copper (Cu), and titanium (Ti) as a single-layer or multilayer structure including the materials. The bottom metal layers BML1 and BML2 may have, for example, a Ti/Al/Ti multi-layered structure.

Subsequently, the buffer layer 111 is formed on the bottom metal layers BML1 and BML2. The buffer layer 111 may be formed of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and/or the like.

Referring to FIG. 5, the driving semiconductor layer A1 is formed on the buffer layer 111 in a region where the driving thin film transistor T1 is to be formed. The driving semiconductor layer A1 may be formed in the region of the driving thin film transistor T1, for example, by applying an oxide semiconductor to the entire surface of the substrate and by patterning the same. In this regard, the oxide semiconductor for the driving semiconductor layer A1 is removed from the region where the switching thin film transistor T2 is to be formed. The oxide semiconductor may be, for example, an oxide of at least one material selected from indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The oxide semiconductor material may include, for example, an indium-gallium-zinc oxide (InGaZnO), a hafnium-indium-zinc oxide (HfInZnO), an indium-tin-zinc oxide (InSnZnO), an aluminum-indium-tin oxide (AlInZnO), a gallium-tin-zinc oxide (GaSnZnO), a gallium-aluminum-zinc oxide (GaAlZnO), an aluminum-tin-zinc oxide (AlSnZnO), an indium-zinc oxide (InZnO), an indium-gallium oxide (InGaO), a zinc-tin oxide (ZnSnO), an aluminum-tin oxide (AlZnO), or any combination thereof. The driving semiconductor layer A1 may be formed of, for example, InGaZnO, HfInZnO, AlInZnO, InZnO, InGaO, AlZnO, and/or the like.

Subsequently, the first gate insulating layer 121 is formed on the driving semiconductor layer A1. After forming the first gate insulating layer 121 on the entire surface of the substrate on which the driving semiconductor layer A1 is formed, the gate insulating layer 121 is removed from the region where the switching thin film transistor T2 is to be formed, thereby leaving behind a portion of the first gate insulating layer 121 that is in the region where the driving thin film transistor T1 is to be formed. The first gate insulating layer 121 may include, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). The first gate insulating layer 121 may be formed to have, for example, a thickness of about 600 Å to about 2000 Å or, for example, a thickness of about 600 Å to about 1000 Å. In the case where the hydrogen concentration of the first gate insulating layer 121 is within the above-described range, a driving voltage range of the driving thin film transistor T1 may be obtained and reliability may be improved (e.g., increased).

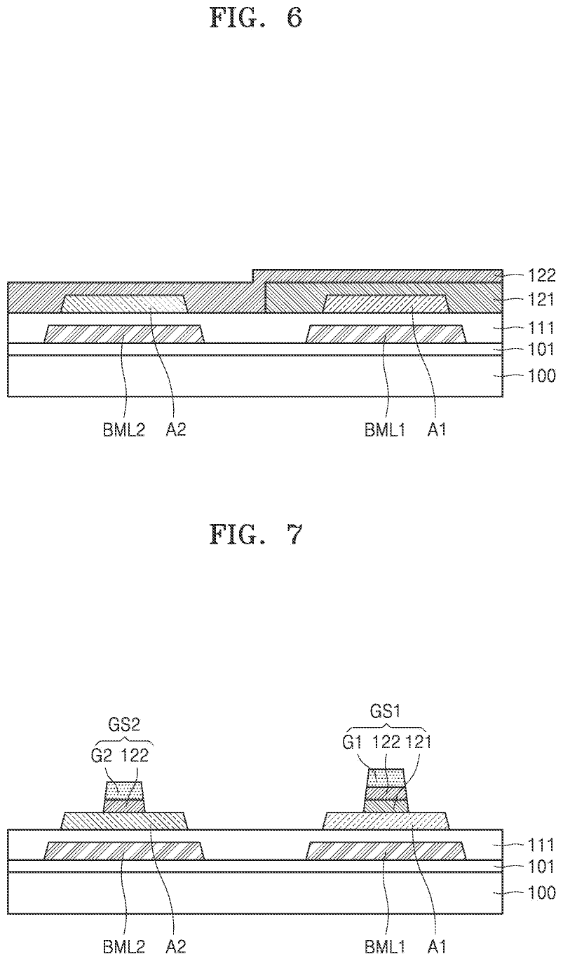

Referring to FIG. 6, the switching semiconductor layer A2 is formed on the buffer layer 111 in the region where the switching thin film transistor T2 is to be formed. The switching semiconductor layer A2 may be formed in the region of the switching thin film transistor T2, for example, by applying an oxide semiconductor to the entire surface of the substrate and patterning the same. In this regard, the oxide semiconductor for the switching semiconductor layer A2 is removed from the region where the driving thin film transistor T1 is to be formed. The oxide semiconductor may be, for example, an oxide of at least one material selected from indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The oxide semiconductor material may include, for example, an indium-gallium-zinc oxide (InGaZnO), a hafnium-indium-zinc oxide (HfInZnO), an indium-tin-zinc oxide (InSnZnO), an aluminum-indium-tin oxide (AlInZnO), a gallium-tin-zinc oxide (GaSnZnO), a gallium-aluminum-zinc oxide (GaAlZnO), an aluminum-tin-zinc oxide (AlSnZnO), an indium-zinc oxide (InZnO), an indium-gallium oxide (InGaO), a zinc-tin oxide (ZnSnO), an aluminum-tin oxide (AlZnO), or any combination thereof. The switching semiconductor layer A2 may be formed of, for example, InSnZnO, InSnGaZnO, GaSnZnO, and/or ZnSnO.

Subsequently, the second gate insulating layer 122 is formed on the entire surface of the substrate. That is, the second gate insulating layer 122 is formed on the first gate insulating layer 121 in the region of the driving thin film transistor T1 and on the switching semiconductor layer A2 in the region of the switching thin film transistor T2. The second gate insulating layer 122 may include, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). The second gate insulating layer 122 may be formed of a material identical to or different from that of the first gate insulating layer 121. The second gate insulating layer 122 may be formed to have a thickness of, for example, about 600 Å to about 2000 Å or, for example, about 1400 Å to about 2000 Å. In the case where the hydrogen concentration of the second gate insulating layer 122 is within the above-described range, a risk of short circuit of the switching thin film transistor T2 may be reduced.

Referring to FIG. 7, the gate electrodes G1 and G2 are concurrently (e.g., simultaneously) formed on the substrate on which the second gate insulating layer 122 is formed. The gate electrode G1 is a gate electrode of the driving thin film transistor T1, and the gate electrode G2 is a gate electrode of the switching thin film transistor T2. The gate electrodes G1 and G2 be formed of one of aluminum (Al), titanium (Ti), tungsten (W), copper (Cu), molybdenum (Mo), platinum (Pt), palladium (Pd), ruthenium (Ru), silver (Ag), magnesium (Mg), gold (Au), nickel (Ni), neodymium (Nd), iridium (Ir), or chromium (Cr), or an alloy, nitride, or conductive oxide thereof. The gate electrodes G1 and G2 may be formed as a single-layer or multilayer structure. As the gate electrodes G1 and G2, for example, Ti/Al, Ti/Mo, or Ti/Al/Ti may be formed, without being limited thereto.

Subsequently, the first gate insulating layer 121 and the second gate insulating layer 122 may be etched using the gate electrodes G1 and G2 as masks to form a driving gate electrode stack GS1 and a switching gate electrode stack GS2. In some examples, the driving gate electrode stack GS1 and the switching gate electrode stack GS2 may be formed by patterning the first gate insulating layer 121 and the second gate insulating layer 122 concurrently (e.g., simultaneously) while the gate electrodes G1 and G2 are formed.

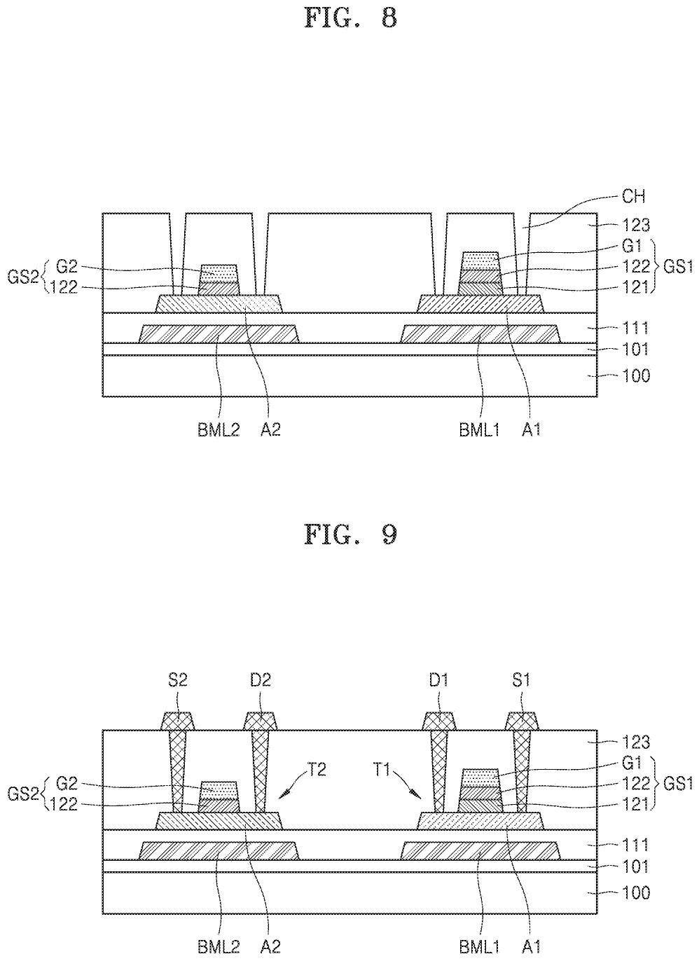

Referring to FIG. 8, the interlayer insulating layer 123 is formed on the substrate on which the gate electrode stacks GS1 and GS2 are formed, contact holes are formed in the interlayer insulating layer 123 to partially expose the semiconductor layers A1 and A2, and the source electrodes S1 and S2 and the drain electrodes D1 and D2 are formed to be connected to the semiconductor layers A1 and A2 via the contact holes.

Referring to FIG. 8, the interlayer insulating layer 123 is formed on the entire surface of the substrate to cover the driving gate electrode G1 and the switching gate electrode G2. The interlayer insulating layer 123 may be formed as a single-layer or multilayer structure of an inorganic material or an organic material. In the case of including an inorganic material, the interlayer insulating layer 123 may be formed of, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or a zinc oxide (ZnO₂). In the case of including an organic material, the interlayer insulating layer 123 may include an organic insulating material such as an acrylic resin, an epoxy resin, a phenol resin, a polyamide resin, and a polyimide resin.

Then, the contact holes CHs are formed in the interlayer insulating layer 123, the contact holes CHs exposing portions of the driving semiconductor layer A1, i.e., portions of a driving source region and a driving drain region, and portions of the switching semiconductor layer A2, i.e., a switching source region and a switching drain region. In some embodiments, the contact holes CHs exposes the bottom electrode layers BML1 and BML2.

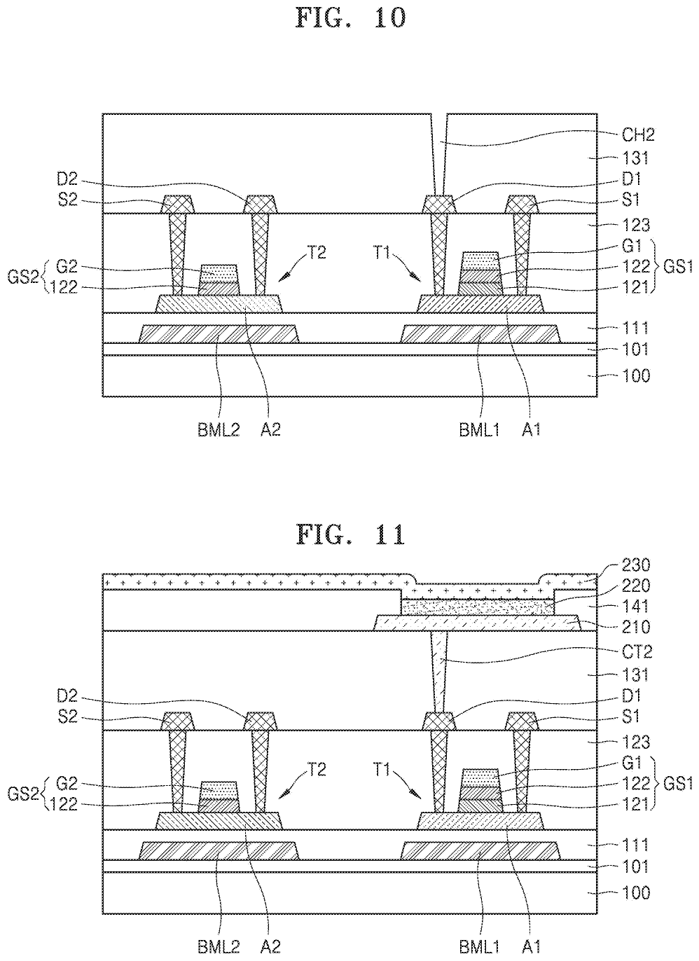

Referring to FIG. 9, the driving source electrode S1, the driving drain electrode D1, the switching source electrode S2, and the driving drain electrode D2 are formed on the interlayer insulating layer 123. The driving source electrode S1, the driving drain electrode D1, the switching source electrode S2, and the driving drain electrode D2 may be formed by depositing a conductive layer on the interlayer insulating layer 123 and patterning the conductive layer. At this time the conductive layer may also fill the contact holes CHs to form contacts CNT. The conductive layer may include aluminum (Al), titanium (Ti), tungsten (W), copper (Cu), molybdenum (Mo), platinum (Pt), palladium (Pd), silver (Ag), magnesium (Mg), gold (Au), nickel (Ni), neodymium (Nd), iridium (Ir), chromium (Cr), and/or the like. A data line may further be formed on the interlayer insulating layer 123.

The driving source electrode S1, the driving drain electrode D1, the switching source electrode S2, and the switching drain electrode D2 may be connected to the driving source region and the driving drain region of the driving semiconductor layer A1 and the switching source region and the switching drain region of the switching semiconductor layer A2, respectively, via contacts CNT. Also, in some embodiments, the driving drain electrode D1 and the switching drain electrode D2 are connected to the bottom metal layers BML1 and BML2, respectively, via contacts CNT.

Referring to FIG. 10, the planarization layer 131 may be formed on the interlayer insulating layer 123 to cover the driving source electrode S1, the driving drain electrode D1, the switching source electrode S2, and the driving drain electrode D2. The planarization layer 131 may include, for example, a photosensitive material and may be formed to have contact holes CH2 that exposes the driving drain electrode D1 by light exposure and curing processes. In some embodiments, a protective layer covering the driving source electrode S1, the driving drain electrode D1, the switching source electrode S2, and the switching drain electrode D2 is formed below the planarization layer 131.

Referring to FIG. 11, a pixel electrode 210 is formed by depositing a conductive layer for pixel electrodes on the planarization layer 131 and patterning the conductive layer. At this time the conductive layer may also fill the contact holes CH2 to form contacts CT2. In some embodiments, the pixel electrode 210 includes a reflective layer formed of silver (Ag), magnesium (Mg), aluminum(Al), platinum (Pt), palladium (Pd), gold (Au), nickel (Ni), neodymium (Nd), iridium (Ir), chromium (Cr), or a compound thereof and a transparent or semi-transparent electrode layer formed on the reflective layer. The transparent or semi-transparent electrode layer includes an indium-tin oxide (ITO), an indium-zinc oxide (IZO), a zinc oxide (ZnO), an indium oxide (In₂O₃), an indium-gallium oxide (IGO), an aluminum-zinc oxide (AZO), or any combination thereof. In some embodiments, the pixel electrode 210 is formed of ITO/Ag/ITO. The pixel electrode 210 may be connected to the driving drain electrode D1 of the driving thin film transistor T1 via a contact CT2.

Subsequently, the pixel-defining layer 141 having an opening OP that covers edges of the pixel electrode 210 and exposes a central region of the pixel electrode 210 is formed on the entire surface of the planarization layer 131. The intermediate layer 220 including an emission layer is formed in the opening OP. The emission layer may include an organic material including a fluorescent or phosphorescent material emitting red, green, blue, or white light. The organic material may be a low-molecular compound or a polymer compound. In some examples, the emission layer may include an inorganic material such as quantum dots. Further, functional layers such as a hole transport layer (HTL), a hole injection layer (HIL), an electron transport layer (ETL), and an electron injection layer (EIL) may further be disposed on and under the emission layer. The intermediate layer 220 may be formed by vacuum deposition, screen printing, inkjet printing, or the like.

Subsequently, the opposite electrode 230 may be formed to correspond to a plurality of organic light-emitting diodes OLEDs. The opposite electrode 230 may be formed to cover the display area DA of the substrate 100 via an open mask.

Each of the layers in the display apparatus according to the disclosure may be formed by any suitable method such as chemical vapor deposition (CVD), plasma-enhanced CVD (PECVD), low pressure CVD (LPCVD), physical vapor deposition (PVD), sputtering, atomic layer deposition (ALD), coating, inkjet printing, and/or screen printing.

### Experimental Example 1

15 thin film transistors were prepared. Each thin film transistor includes an Al/Ti bottom metal layer having a thickness of 3500/300 Å, a Si₃N₄/SiO₂ buffer layer formed on the bottom metal layer and having a thickness of 2000/1000 Å, an ITGZO semiconductor layer formed on the buffer layer and having a thickness of 300 Å, a SiO₂ second gate insulating layer formed on the semiconductor layer and having a thickness of 1400 Å, a Ti/Mo gate electrode formed on the second gate insulating layer and having a thickness of 300/2500 Å, and a Ti/Al/Ti source/drain electrode having a thickness of 300/6000/700 Å.

### Comparative Example 1

15 thin film transistors were prepared. Each thin film transistor includes an Al/Ti bottom metal layer having a thickness of 3500/300 Å, a Si₃N₄/SiO₂ buffer layer formed on the bottom metal layer and having a thickness of 2000/1000 Å, a SiO₂ first gate insulating layer formed on the buffer layer and having a thickness of 1000 Å, an ITGZO semiconductor layer formed on the first gate insulating layer and having a thickness of 300 Å, a SiO₂ second gate insulating layer formed on the semiconductor layer and having a thickness of 1400 Å, a Ti/Mo gate electrode formed on the second gate insulating layer and having a thickness of 300/2500 Å, and a Ti/Al/Ti source/drain electrode having a thickness of 300/6000/700 Å.

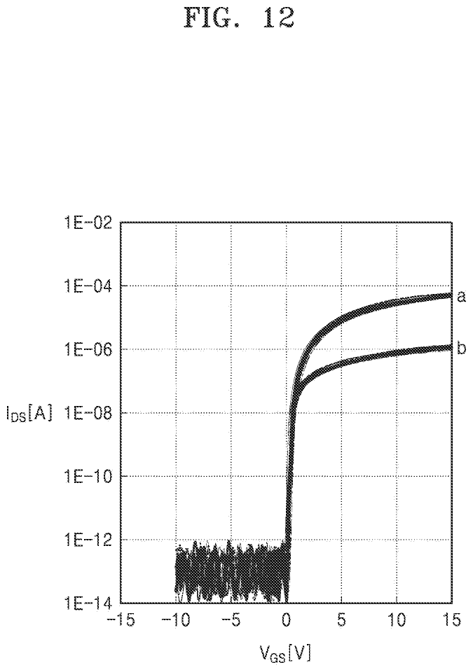

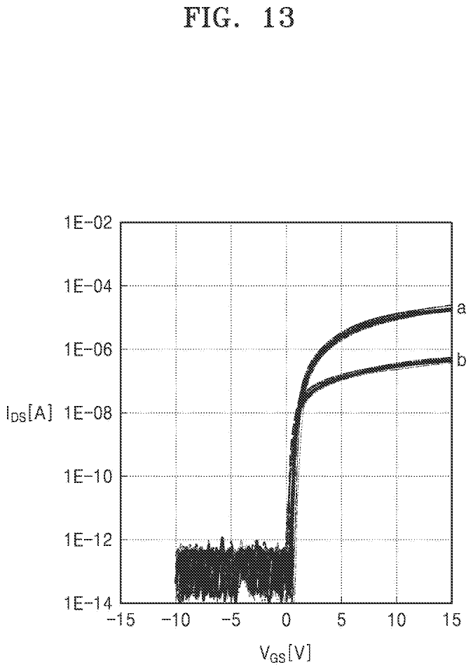

FIG. 12 is a graph illustrating drain-source currents I_{DS} with respect to gate-source voltages V_{GS} of 15 thin film transistors prepared in Experimental Example 1. FIG. 13 is a graph of drain-source currents I_{DS} with respect to gate-source voltages V_{GS} of 15 thin film transistors prepared in Comparative Example 1. Curves (a) and (b) of FIGS. 12 and 13 respectively show cases in which the drain voltages were 5.1 V and 0.1 V.

Table 1 shows comparison results of average device data between the 15 thin film transistors prepared according to Experimental Example 1 and the 15 thin film transistors prepared according to Comparative Example 1. In Table 1, I_{ON} indicates an I_{DS} value at a V_{GS} of 15 V, and DR1 indicates a difference between V_{GS} values obtained at an I_{ON} value of 10 pA and an I_{ON} value of 10 nA. In Table 1, the I_{ON}, mobility, and DR1 are values obtained at a drain voltage of 5.1 V, the VTH (0.1) is a threshold voltage at a drain voltage of 0.1 V, and the VTH (5.1) is a threshold voltage at a drain voltage of 5.1 V.

TABLE 1

| | I_{ON} | Mobility | V_{TH} (0.1) | V_{TH} (5.1) | DR1 |
|---|---|---|---|---|---|
| | (A) | (cm²/V · s) | (V) | (V) | (V) |
| Experimental | 5.3E−05 | 59.61 | 0.40 | 0.51 | 0.29 |
| Example 1 | | | | | |
| Comparative | 2.3E−05 | 27.87 | 0.83 | 1.19 | 0.31 |
| Example 1 | | | | | |

The thin film transistors of Experimental Example 1 have a buffer layer/oxide semiconductor layer/second gate insulating layer/gate electrode structure, and the thin film transistors of Comparative Example 1 have a buffer layer/first gate insulating layer/oxide semiconductor layer/second gate insulating layer/gate electrode structure. Referring to Table 1, the thin film transistor of Experimental Example 1 had the On-current I_{ON} of 5.3E-5 A, which was higher than the On-current (2.3E-5 A) of the thin film transistor of Comparative Example 1 by about 130%, and the electron mobility of 59.61 cm²/V·s, which was higher than the electron mobility (27.87 cm²/V·s) of the thin film transistor of Comparative Example 1 by about 110%. It is considered that these results are obtained because the thin film transistor of Experimental Example 1 is less affected by the first gate insulating layer, for example, by additional influx of oxygen from the first gate insulating layer to the oxide semiconductor layer compared to the thin film transistor of Comparative Example 1.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

It should be understood that embodiments described herein should be considered in a descriptive sense only and not for purposes of limitation. Descriptions of features or aspects within each embodiment should typically be considered as available for other similar features or aspects in other embodiments. While some embodiments have been described with reference to the figures, it will be understood by those of ordinary skill in the art that various changes in form and details may be made therein without departing from the spirit and scope as defined by the following claims, and equivalents thereof.

What is claimed is:

1. A method of fabricating a display apparatus, the method comprising:
providing a substrate having a first thin film transistor region and a second thin film transistor region;
forming a first oxide semiconductor layer on the substrate in the first thin film transistor region;
forming a first gate insulating layer covering the first oxide semiconductor layer in the first thin film transistor region;
forming a second oxide semiconductor layer on the substrate in the second thin film transistor region;
forming a second gate insulating layer on the substrate on which the first gate insulating layer and the second oxide semiconductor layer are formed;
forming a first gate electrode in the first thin film transistor region and forming a second gate electrode in the second thin film transistor region, over the second gate insulating layer; and
forming a first gate electrode stack and a second gate electrode stack by etching the first gate insulating layer, which is under the first gate electrode, and etching the second gate insulating layer, which is under the first and second gate electrodes, by using the first gate electrode and the second gate electrode as etching masks.

2. The method of claim 1, wherein the forming of the first gate insulating layer comprises:
forming an insulating layer for the first gate insulating layer on the substrate; and
removing a portion of the insulating layer from the second thin film transistor region.

3. The method of claim 1, further comprising:
forming an interlayer insulating layer on the substrate;
forming, on the interlayer insulating layer, a first source electrode and a first drain electrode to be in contact with the first oxide semiconductor layer, and a second source electrode and a second drain electrode to be in contact with the second oxide semiconductor layer;
forming a planarization layer on the interlayer insulating layer, the first source electrode, the first drain electrode, the second source electrode, and the second drain electrode; and
forming an organic light-emitting device that is connected to the first source electrode or the first drain electrode on the planarization layer.

4. The method of claim 1, wherein a thickness of each of the first gate insulating layer and the second gate insulating layer is from about 600 Å to about 2000 Å.

5. The method of claim 1, wherein each of the first gate insulating layer and the second gate insulating layer comprises at least one of silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂).

6. The method of claim 5, wherein the first gate insulating layer and the second gate insulating layer are formed of a same material.

7. The method of claim 5, wherein the first gate insulating layer and the second gate insulating layer are formed of different materials from each other.

8. The method of claim 1, wherein a concentration of hydrogen in the first gate insulating layer is higher than a concentration of hydrogen in the second gate insulating layer.

9. The method of claim 1, wherein the second oxide semiconductor layer has a higher electron mobility than that of the first oxide semiconductor layer.

10. The method of claim 9, wherein the first oxide semiconductor layer has an electron mobility of about 1 to about 20 cm²/V·s, and
wherein the second oxide semiconductor layer has an electron mobility of about 30 to about 80 cm²/V·s.

11. The method of claim 9, wherein each of the first oxide semiconductor layer and the second oxide semiconductor layer comprises an indium-gallium-zinc oxide (InGaZnO), a hafnium-indium-zinc oxide (HfInZnO), an indium-tin-zinc oxide (InSnZnO), an aluminum-indium-tin oxide (AlInZnO), a gallium-tin-zinc oxide (GaSnZnO), a gallium-aluminum-zinc oxide (GaAlZnO), an aluminum-tin-zinc oxide (AlSnZnO), an indium-zinc oxide (InZnO), an indium-gallium oxide (InGaO), a zinc-tin oxide (ZnSnO), an aluminum-tin oxide (AlZnO), or any combination thereof.

12. The method of claim 11, wherein the first oxide semiconductor layer comprises InGaZnO, HfInZnO, AlInZnO, InZnO, InGaO, AlZnO, or any combination thereof, and the second oxide semiconductor layer comprises InSnZnO, InSnGaZnO, GaSnZnO, ZnSnO, or any combination thereof.

13. The method of claim 1, wherein the substrate further comprises:
a first bottom metal layer in the first thin film transistor region;
a second bottom metal layer in the second thin film transistor region; and
a buffer layer on the first bottom metal layer and the second bottom metal layer,
wherein the first gate electrode and the first bottom metal layer face each other, and the second gate electrode and the second bottom metal layer face each other.

14. A display apparatus comprising:
an organic light-emitting device;
a first thin film transistor connected to the organic light-emitting device; and
a second thin film transistor on a same plane as that of the first thin film transistor,
wherein the first thin film transistor comprises:
a first oxide semiconductor layer;
a first gate electrode stack comprising a first gate insulating layer on the first oxide semiconductor layer, a second gate insulating layer on the first gate insulating layer, and a first gate electrode on the second gate insulating layer; and
a first source electrode and a first drain electrode, both contacting the first oxide semiconductor layer,
wherein the second thin film transistor comprises:
a second oxide semiconductor layer;
a second gate electrode stack comprising a second gate insulating layer on the second oxide semiconductor layer, and a second gate electrode on the second gate insulating layer; and
a second source electrode and a second drain electrode, both contacting the second oxide semiconductor layer,
wherein an electron mobility of the second oxide semiconductor layer is higher than that of the first oxide semiconductor layer.

15. The display apparatus of claim 14, wherein each of the first gate electrode and the second gate electrode comprises one of aluminum (Al), titanium (Ti), tungsten (W), copper (Cu), molybdenum (Mo), platinum (Pt), palladium (Pd), ruthenium (Ru), silver (Ag), magnesium (Mg), gold (Au), nickel (Ni), neodymium (Nd), iridium (Ir), and chromium (Cr), or an alloy, nitride, or conductive oxide thereof.

16. The display apparatus of claim 14, wherein the first thin film transistor is a driving thin film transistor connected to the organic light-emitting device, and the second thin film transistor is a switching thin film transistor connected to the driving thin film transistor.

17. The display apparatus of claim 14, wherein each of the first oxide semiconductor layer and the second oxide semiconductor layer comprises an indium-gallium-zinc oxide (InGaZnO), a hafnium-indium-zinc oxide (HfInZnO), an indium-tin-zinc oxide (InSnZnO), an aluminum-indium-tin oxide (AlInZnO), a gallium-tin-zinc oxide (GaSnZnO), a gallium-aluminum-zinc oxide (GaAlZnO), an aluminum-tin-zinc oxide (AlSnZnO), an indium-zinc oxide (InZnO), an indium-gallium oxide (InGaO), a zinc-tin oxide (ZnSnO), an aluminum-tin oxide (AlZnO), or any combination thereof.

18. The display apparatus of claim 14, wherein a total thickness of the first gate insulating layer and the second gate insulating layer, between the first oxide semiconductor layer and the first gate electrode, is greater than a thickness of the second gate insulating layer between the second oxide semiconductor layer and the second gate electrode.

19. The display apparatus of claim 14, further comprising:
a first bottom metal layer under the first oxide semiconductor layer and overlapping the first gate electrode stack;
a second bottom metal layer under the second oxide semiconductor layer and overlapping the second gate electrode stack; and
a buffer layer between the first gate electrode stack and the first bottom metal layer and between the second gate electrode stack and the second bottom metal layer.

20. The display apparatus of claim 14, wherein the display apparatus comprises a flat panel display, a curved display, a computer monitor, a medical monitor, a television, a billboard, a light for indoor or outdoor lighting and/or signal lighting, a head-up display, a fully or partially transparent display, a flexible display, a rollable display, a foldable display, a stretchable display, a laser printer, a phone, a mobile phone, a tablet, a phablet, a personal digital assistant (PDA), a wearable device, a laptop computer, a digital camera, a camcorder, a viewfinder, a microdisplay, a 3D display, a virtual reality or augmented reality display, a vehicle, a video wall comprising multiple displays tiled together, a theater or stadium screen, a phototherapy device, or a signage.
